(19) United States
(12) Patent Application Publication
(10) Pub. No.: US 2007/0195615 A1
(43) Pub. Date: Aug. 23, 2007

(54) METHOD AND CIRCUIT FOR REAL-TIME CALIBRATING DATA CONTROL SIGNAL AND DATA SIGNAL

(75) Inventor: Yi Lin CHEN, Taipei City (TW)

Correspondence Address: LOWE HAUPTMAN BERNER, LLP, 1700 DIAGONAL ROAD, SUITE 300, ALEXANDRIA, VA, 22314, US

(73) Assignee: REALTEK SEMICONDUCTOR CORP., Hsinchu (TW)

(21) Appl. No.: 11/675,554

(22) Filed: Feb. 15, 2007

(30) Foreign Application Priority Data
Feb. 21, 2006 (TW) 095105710

(51) Int. Cl. G11C 7/00; G11C 7/06

(52) U.S. Cl. 365/193; 365/189.07

(57) ABSTRACT

A real-time calibrating circuit comprises a first comparator, a second comparator, a phase detector, at least one control circuit, and at least one output driving circuit for driving a data control signal or a data signal, wherein the first and the second comparators compare the voltage values of two complementary signals and a direct-current voltage and respectively output a first comparison signal and a second comparison signal according to the results of comparing the voltage values; the phase detector outputs a phase difference signal according to the phase difference of the first and second comparison signals; the control circuit adjusts the output driving circuit according to the phase difference signal, whereby calibrating the data control signal or the data signal. The present invention also provides a real-time calibrating method for a data control signal and a data signal.

### CROSS REFERENCE TO RELATED APPLICATION

This application claims the priority benefit of Taiwan Patent Application Serial Number 095105710, filed on Feb. 21, 2006, the full disclosure of which is incorporated herein by reference.

### BACKGROUND OF THE INVENTION

1. Field of the Invention

This invention generally relates to a calibrating circuit and method, and more particularly to a real-time calibrating circuit and method for a data control signal and a data signal.

2. Description of the Related Art

FIG. 1 shows a schematic view of a conventional memory controller 10 coupled to a double data rate (DDR) memory 12. The memory controller 10 utilizes a bi-directional data strobe signal DQS to write a data signal DQ into the DDR memory 12 or to read the data signal DQ from the DDR memory 12. During writing operations, the memory controller 10 transmits the data strobe signal DQS with the data signal DQ to the DDR memory 12. In addition, during reading operations, the DDR memory 12 transmits the data strobe signal DQS with the data signal DQ to the memory controller 10.

In general, the DDR memory 12 can transfer data on each rising and falling edge of the data strobe signal DQS. Therefore, the transition time of each rising edge, i.e. rising time, and the transition time of each falling edge, i.e. falling time, are relatively significant for the captured data. Ideally, the rising time is equal to the falling time at the data strobe signal DQS.

Conventionally, the data strobe signal DQS can be outputted by an output driving circuit 14 as shown in FIG. 2. The output driving circuit 14 includes at least one PMOS transistor 14a and one NMOS transistor 14b and has an output terminal 15 for outputting the data strobe signal DQS. When the PMOS transistor 14a and the NMOS transistor 14b have the same driving ability, the output terminal 15 will output a data strobe signal DQS as shown in FIG. 3, of which the rising time tr and the falling time tf are equal. However, due to the difference between the process for making the PMOS transistor 14a and the process for making the NMOS transistor 14b, the PMOS transistor 14a and the NMOS transistor 14b generally have different driving abilities such that the rising time tr and the falling time tf of the data strobe signal DQS are unequal. For example, if the driving ability of the PMOS transistor 14a is weaker than that of the NMOS transistor 14b, the rising time tr will be longer than the falling time tf. On the contrary, if the driving ability of the PMOS transistor 14a is stronger than that of the NMOS transistor 14b, the rising time tr will be shorter than the falling time tf.

In addition, since the data signal DQ is also outputted by an output driving circuit, which is the same with the output driving circuit 14 shown in FIG. 2, the rising time and the falling time of the data signal DQ are also unequal.

Since the rising and falling times of the signals DQS and DQ may limit the time for capturing data and even significantly under high speed data transmission, an off-chip driver (OCD) method has been proposed in DDR II memory standard for improving the above problems. When the memory controller 10 is under a power-on reset (POR) procedure or when the signals DQS and DQ are not used, the OCD method is performed to adjust the driving ability of the output driving circuit 14, such that the respective rising and falling times of the signals DQS and DQ can be adjusted to be closer or equal. The application of the OCD method can be referred to U.S. Pat. No. 6,885,959, the whole disclosure of which is incorporated herein by reference.

After the OCD method is performed, the memory controller 10 begins reading and writing operations with the DDR memory 12. However, when the operation time of the memory controller 10 and the DDR memory 12 increases, the operation temperature will gradually rises, such that the respective driving abilities of the PMOS transistor 14a and the NMOS transistor 14b in the output driving circuit 14 would vary with the change of the operation temperature and thus again cause the unequal of the rising and falling times of the data strobe signal DQS and the data signal DQ. Therefore, the data strobe signal DQS and the data signal DQ should wait until the power-on reset is performed, and then can be adjusted by another ODC adjustment. During this waiting period, unequal of the rising and falling times of the data strobe signal DQS and the data signal DQ may limit the time for capturing data and even affect the validity of the captured data.

Accordingly, the present invention provides a method and circuit for real-time calibrating a data strobe signal and a data signal whereby solving the above-mentioned problems in the prior art.

### SUMMARY OF THE INVENTION

It is an object of the present invention to provide a real-time calibrating circuit and method, which can instantaneously calibrate a data control signal and a data signal whereby solving the problem caused by the unequal rising time and the falling time at the data control signal and the data signal.

In order to achieve the above object, the present invention provides a real-time calibrating circuit for a data control signal and a data signal, which comprises a first comparator, a second comparator, a phase detector, at least one control circuit, and at least one output driving circuit for driving the data control signal or the data signal, wherein the first and the second comparators compare two complementary signals and a direct-current voltage and respectively output a first comparison signal and a second comparison signal according to results; the phase detector outputs a phase difference signal according to the phase difference of the first and second comparison signals; the control circuit adjusts the driving ability of the output driving circuit according to the phase difference signal, whereby calibrating the data control signal or the data signal.

The present invention also provides a real-time calibrating method for a data control signal and a data signal, comprising the following steps: providing a first signal and a second signal being complementary to each other and both having a high voltage level and a low voltage level, wherein the first signal has a first cross point with the second signal at a first time; providing a direct-current voltage having a direct-current voltage level positioned between the high voltage level and the low voltage level, wherein the direct-current voltage level has a second cross point with the first signal at a second time and a third cross point with the second signal at a third time; and calibrating one of the data strobe signal and the data signal according to a time sequence of two of the first time, the second time and the third time.

The present invention also provides a real-time method for calibrating a data control signal and a data signal, comprising: comparing a first signal and a second signal and outputting a first comparison signal; comparing a third signal and a fourth signal and outputting a second comparison signal, wherein two of the first signal, the second signal, the third signal and the fourth signal are complementary to each other, and both the two complementary signals have a high voltage level and a low voltage level; receiving the first comparison signal and the second comparison signal and outputting a phase difference signal according to the phase difference between the first comparison signal and the second comparison signal; driving the two complementary signals respectively; adjusting two first output driving circuits respectively according to the phase difference signal; driving at least one of the data control signal and the data signal; and adjusting a second output driving circuit according to the phase difference signal to calibrate at least one of the data control signal and the data signal.

### BRIEF DESCRIPTION OF THE DRAWINGS

Other objects, advantages, and novel features of the present invention will become more apparent from the following detailed description when taken in conjunction with the accompanying drawings.

FIG. 1 shows a schematic view of a conventional memory controller coupled to a double data rate (DDR) memory.

FIG. 2 shows a schematic view of a conventional output driving circuit.

FIG. 3 shows a schematic waveform of a data strobe signal DQS.

FIG. 4 shows a circuit block diagram of a real-time calibrating circuit according to one embodiment of the present invention.

FIG. 5 shows the waveforms CK1, CK2, DQS and DQ in the real-time calibrating circuit shown in FIG. 4.

FIG. 6 shows the waveforms CK1 and CK2 in other embodiments of the present invention.

FIG. 7 shows a circuit block diagram of a real-time calibrating circuit according to another embodiment of the present invention.

FIG. 8 shows a circuit block diagram of a real-time calibrating circuit according to another embodiment of the present invention.

### DETAILED DESCRIPTION OF THE PREFERRED EMBODIMENT

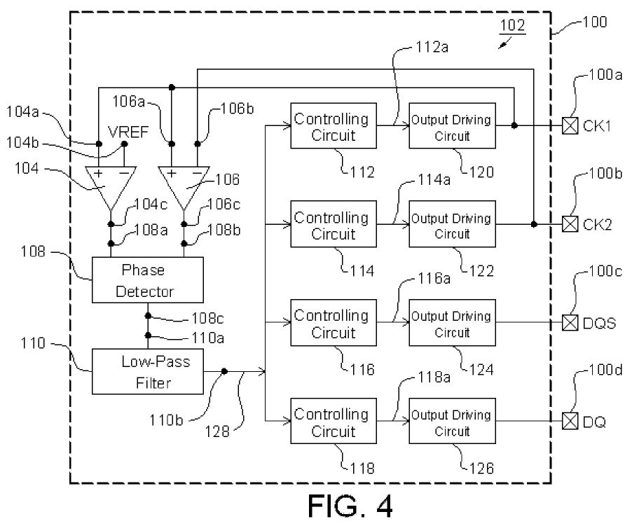

FIG. 4 is a circuit block diagram of a real-time calibrating circuit 102 according to one embodiment of the present invention. The real-time calibrating circuit 102 is disposed inside a double data rate (DDR) memory controller 100 and includes a first comparator 104, a second comparator 106, a phase detector 108, a low-pass filter 110, four controlling circuits 112, 114, 116, 118, and four output driving circuits 120, 122, 124, 126.

In the real-time calibrating circuit 102, each output driving circuit 120, 122, 124, 126 includes at least one PMOS transistor and at least one NMOS transistor as shown in FIG. 2 and is made by the same processes. The driving ability of the PMOS transistor can determine the rising time of an output signal, and the driving ability of the NMOS transistor can determine the falling time of the output signal.

The output driving circuit 120 outputs a clock signal CK1 and transmits the clock signal CK1 to an output 100a of the DDR memory controller 100. The output driving circuit 122 outputs a clock signal CK2 and transmits the clock signal CK2 to an output 100b of the DDR memory controller 100. The output driving circuit 124 outputs a data strobe signal DQS and transmits the data strobe signal DQS to an output 100c of the DDR memory controller 100. The output driving circuit 126 outputs a data signal DQ and transmits the data signal DQ to an output 100d of the DDR memory controller 100. In addition, the clock signal CK1 and the clock signal CK2 are two complementary clock signals in DDR memory standard.

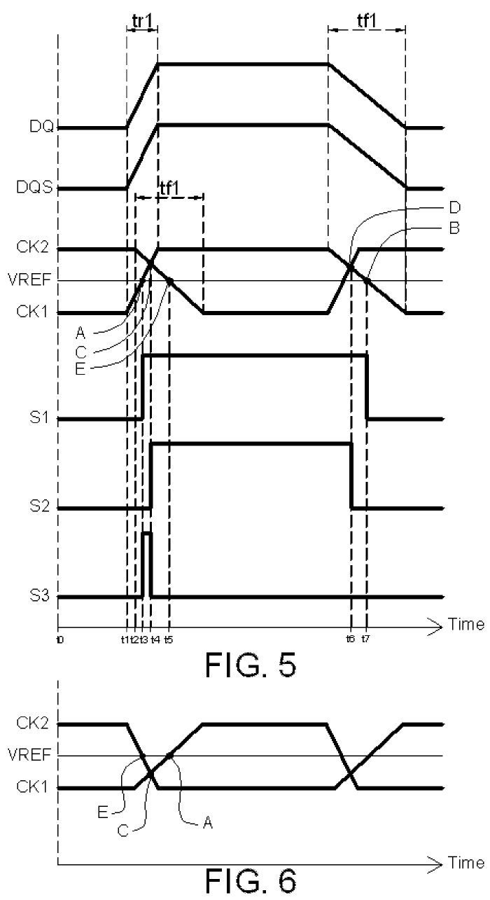

In this embodiment, the PMOS transistors and the NMOS transistors of the output driving circuits 120, 122, 124, 126 are respectively formed by the same processes. Therefore, the rising edges of the output signals CK1, CK2, DQS and DQ have the same driving performance according to the driving ability of the PMOS transistor, and the falling edges of the output signals CK1, CK2, DQS and DQ have the same driving performance according to the driving ability of the NMOS transistor. For clearly illustrating the operation of the real-time calibrating circuit 102, assuming that the driving ability of the PMOS transistor is stronger than that of the NMOS transistor in the output driving circuit 120, 122, 124, 126. The output signals CK1, CK2, DQS, and DQ are presented as shown in FIG. 5. Since the driving ability of the PMOS transistor is stronger than that of the NMOS transistor in the output driving circuit 120, 122, 124, 126, the rising time tr1 is shorter than the falling time tf1 at the respective signals CK1, CK2, DQS and DQ. The operation of the real-time calibrating circuit 102 and the real-time calibrating method according to the present invention are described below.

Firstly, the first comparator 104 receives the clock signal CK1 by an input 104a and receives a dc (direct-current) reference voltage VREF by an input 104b. The dc voltage level of the dc reference voltage VREF is positioned between the high voltage level and the low voltage level of the clock signal CK1/CK2. According to one embodiment of the present invention, the dc voltage level of the dc reference voltage VREF is positioned at the middle between the high voltage level and the low voltage level as shown in FIG. 5. And in this embodiment, the first comparator 104 is implemented by an operational amplifier, wherein the input 104a is a non-inverting input and the input 104b is an inverting input. After the first comparator 104 receives the clock signal CK1 and the dc reference voltage VREF, the first comparator 104 outputs a comparison signal S1, as shown in FIG. 5, by the output 104c according to the voltage levels of the clock signal CK1 and the dc reference voltage VREF The comparison signal S1 is presented as a low voltage level, e.g. during time t0 to t3, while the voltage level of the clock signal CK1 is smaller than that of the dc reference voltage VREF; and the comparison signal S1 is presented as a high voltage level, e.g. during time t3 to t7, while the voltage level of the clock signal CK1 is larger than that of the dc reference voltage VREF. At time t3, the rising edge of the clock signal CK1 has a voltage cross point A with the voltage level of the dc reference voltage VREF, and the comparison signal S1 transits from the low voltage level to the high voltage level at the time the voltage cross point A occurs. At time t7, the falling edge of the clock signal CK1 has a voltage cross point B with the voltage level of the dc reference voltage VREF, and the comparison signal S1 transits from the high voltage level to the low voltage level at the time the voltage cross point B occurs.

In addition, the second comparator 106 receives the clock signal CK1 by an input 106a and receives the clock signal CK2 by the other input 106b. The second comparator 106 is also implemented by an operational amplifier, wherein the input 106a is a non-inverting input and the input 106b is an inverting input. After the second comparator 106 receives the clock signals CK1 and CK2, the second comparator 106 outputs a comparison signal S2, as shown in FIG. 5, by the output 106c according to the voltage levels of the clock signals CK1 and CK2. The comparison signal S2 is presented as a low voltage level, e.g. during time t0 to t4, while the voltage level of the clock signal CK1 is smaller than that of the clock signal CK2; and the comparison signal S2 is presented as a high voltage level, e.g. during time t4 to t6, while the voltage level of the clock signal CK1 is larger than that of the clock signal CK2. At time t4, the rising edge of the clock signal CK1 has a voltage cross point C with the falling edge of the clock signal CK2, and the comparison signal S2 transits from the low voltage level to the high voltage level at the time the voltage cross point C occurs. At time t6, the falling edge of the clock signal CK1 has a voltage cross point D with the rising edge of the clock signal CK2, and the comparison signal S2 transits from the high voltage level to the low voltage level at the time the voltage cross point D occurs.

In this embodiment, the time sequence of the voltage cross point A of the clock signal CK1 and the dc reference voltage VREF and the voltage cross point C of the clock signals CK1 and CK2 determine the driving performances of the clock signals CK1 and CK2. For example, if the voltage cross point A occurs prior to the voltage cross point C, the rising time of the clock signal CK1 is shorter than the falling time of the clock signal CK2 as shown in FIG. 5. On the contrary, if the voltage cross point A occurs behind the voltage cross point C, the rising time of the clock signal CK1 is longer than the falling time of the clock signal CK2 as shown in FIG. 6. In this embodiment, since the voltage cross point A occurs prior to the voltage cross point C, it can be determined that the rising time tr1 of the clock signal CK1 is shorter than the falling time tf1 of the clock signal CK2. Further, the rising edges of the signals CK1, CK2, DQS and DQ, as described above, have the same driving performances according to the driving ability of the PMOS transistor, and the falling edges of them have the same driving performances according to the driving ability of the NMOS transistor. Therefore, it can also be determined that the rising time tr1 is shorter than the falling time tf1 at the respective signals CK1, CK2, DQS and DQ.

After the comparison signals S1 and S2 are outputted from the comparators 104 and 106, the comparison signals S1 and S2 are transmitted to two inputs 108a and 108b of the phase detector 108, respectively. Afterward, the phase detector 108 detects the phase difference between the comparison signals S1 and S2 and outputs a phase difference signal S3, as shown in FIG. 5, by its output 108c according to the phase difference, and the phase difference signal S3 presents the phase relationship between the comparison signals S1 and S2. In this embodiment, the phase detector 108 detects the phase difference between the rising edges of the comparison signals S1 and S2, and generates a positive voltage pulse if the comparison signal S1 leads ahead of the comparison signal S2 in phase, generates a negative voltage pulse if the comparison signal S1 lags behind the comparison signal S2 in phase, and remains unchanged if the comparison signal S1 is equal to the comparison signal S2 in phase. As shown in FIG. 5, since the comparison signal S1 leads ahead of the comparison signal S2 in phase, the phase difference signal S3 outputted by the phase detector 108 has a positive voltage pulse during time t3 to t4.

In this embodiment, the positive voltage pulse of the phase difference signal S3 presents that the voltage cross point A occurs prior to the voltage cross point C, meaning that the rising time tr1 is shorter than the falling time tf1 at the respective signals CK1, CK2, DQS and DQ. On the contrary, if the phase difference signal S3 has a negative voltage pulse, it presents that the voltage cross point A occurs behind the voltage cross point C, meaning that the rising time tr1 is longer than the falling time tf1 at the respective signals CK1, CK2, DQS and DQ.

After the phase difference signal S3 is outputted by the phase detector 108, the phase difference signal S3 is transmitted to an input 110a of the low-pass filter 110. The low-pass filter 110 filters the high-frequency part out of the phase difference signal S3, and then outputs a result signal 128 through its output 110b. Meanwhile, the result signal 128 presents that the voltage cross point A occurs prior to the voltage cross point C, meaning that the rising time tr1 is shorter than the falling time tf1 at the respective signals CK1, CK2, DQS and DQ. Afterward, the control circuits 112, 114, 116 and 118 receive the result signal 128 and respectively output control signals 112a, 114a, 116a and 118a according to the result signal 128 for adjusting the driving abilities of the output driving circuits 120, 122, 124, and 126.

In this embodiment, since the result signal 128 presents that the rising time tr1 is shorter than the falling time tf1 at the respective signals CK1, CK2, DQS and DQ, the control signals 112a, 114a, 116a and 118a outputted by the control circuits 112, 114, 116 and 118 will respectively adjust the driving abilities of the NMOS transistors disposed in the output driving circuits 120, 122, 124 and 126, to increase one scale or one step. In this manner, the falling time tf1 can be shortened according to the increment of the driving ability of the NMOS transistor and become closer to the rising time tr1 at the respective signals CK1, CK2, DQS and DQ. Alternatively, the control signals 112a, 114a, 116a and 118a outputted by the control circuits 112, 114, 116 and 118 can also respectively adjust the driving abilities of the PMOS transistors disposed in the output driving circuits 120, 122, 124 and 126, to decrease one scale or one step. In this manner, the rising time tr1 can be lengthened according to the decrement of the driving ability of the PMOS transistor and become closer to the length of the falling time tf1 at the respective signals CK1, CK2, DQS and DQ.

After the driving abilities of the NMOS transistors and the PMOS transistors in the output driving circuits 120, 122, 124 and 126 are adjusted, the rising time tr1 and the falling time tf1 at the respective signals CK1, CK2, DQS and DQ outputted by the output driving circuits 120, 122, 124 and 126 become closer to each other in length. Meanwhile, the outputted clock signals CK1 and CK2 are re-transmitted back to the first and second comparators 104 and 106 of the real-time calibrating circuit 102, and then are processed through the phase detector 108 and the low-pass filter 110 so as to determine whether the driving abilities of the output driving circuits 120, 122, 124 and 126 should be adjusted again. In addition, if the rising time tr1 and the falling time tf1 at the respective clock signals CK1 and CK2 become equal in length after the calibration of the real-time calibrating circuit 102, the result signal 128 outputted by the low-pass filter 110 will inform the control circuits 112, 114, 116 and 118 not to adjust the driving abilities of the output driving circuits 120, 122, 124 and 126.

In the real-time calibrating circuit 102 according to the embodiment of the present invention, the clock signals CK1 and CK2 are transmitted to the first and second comparators 104 and 106 while being transmitted to the outputs 100a and 100b, and then the clock signals CK1 and CK2 are processed by the phase detector 108 and the low-pass filter 110 so as to determine whether the driving abilities of the output driving circuits 120, 122, 124 and 126 should be adjusted again. Therefore, the real-time calibrating circuit 102 can instantaneously calibrate the signals CK1, CK2, DQS and DQ anytime according to the driving performances of the rising and falling edges of the clock signals CK1 and CK2, such that the length of the rising time tr1 and that of the falling time tr1 can be closer or equal. Accordingly, when the lengths of the rising time tr1 and falling time tr1 at the respective signals CK1, C 2, DQS and DQ become unequal due to the effects of temperature change or other unexpected factors, the real-time calibrating circuit 102 can calibrate the signals CK1, CK2, DQS and DQ according to the driving performances of the rising and falling edges of the clock signals CK1 and CK2 whereby solving the problem caused by the unequal lengths of the rising time and the falling time at the data strobe signal DQS and the data signal DQ.

As shown in FIG. 5, it can be seen that the clock signal CK2 has a voltage cross point E with the voltage level of the dc reference voltage VREF at time t5. Therefore, in another embodiment of the present invention, the driving performances of the clock signals CK1 and CK2 can also be determined by the time sequence of the voltage cross point C and the voltage cross point E so as to achieve the object of calibrating the data strobe signal DQS and the data signal DQ. For example, if the voltage cross point C occurs prior to the voltage cross point E, the rising time of the clock signal CK1 is shorter than the falling time of the clock signal CK2 as shown in FIG. 5. On the contrary, if the voltage cross point C occurs behind the voltage cross point E, the rising time of the clock signal CK1 is longer than the falling time of the clock signal CK2 as shown in FIG. 6.

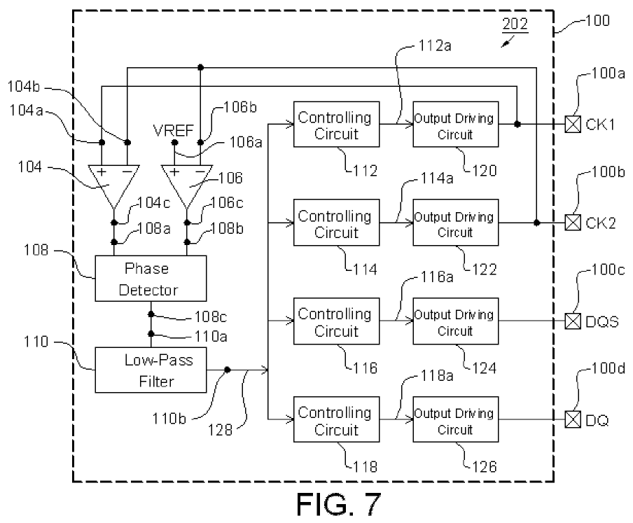

FIG. 7 shows a real-time calibrating circuit 202, which can achieve the object of calibrating the data strobe signal DQS and the data signal DQ by comparing the time sequence of the voltage cross point C and the voltage cross point E. The real-time calibrating circuit 202 shown in FIG. 7 is substantially identical to the real-time calibrating circuit 102 shown in FIG. 4, except that the first comparator 104 and the second comparator 106 have their inputs 104b, 106a and 106b receive difference signals.

In the real-time calibrating circuit 202, the first comparator 104 receives the clock signal CK1 by its input 104a and receives the clock signal CK2 by its input 104b. In addition, the second comparator 106 receives the dc reference voltage VREF by its input 106a and receives the clock signal CK2 by its input 106b. Since the operation of the real-time calibrating circuit 202 is similar to the real-time calibrating circuit 102 shown in FIG. 4, it will not be illustrated herein in detail.

In addition, in another embodiment of the present invention, the driving performances of the clock signals CK1 and CK2 can also be determined by the time sequence of the voltage cross point A and the voltage cross point E so as to achieve the object of calibrating the data strobe signal DQS and the data signal DQ. For example, if the voltage cross point A occurs prior to the voltage cross point E, the rising time of the clock signal CK1 is shorter than the falling time of the clock signal CK2 as shown in FIG. 5. On the contrary, if the voltage cross point A occurs behind the voltage cross point E, the rising time of the clock signal CK1 is longer than the falling time of the clock signal CK2 as shown in FIG. 6.

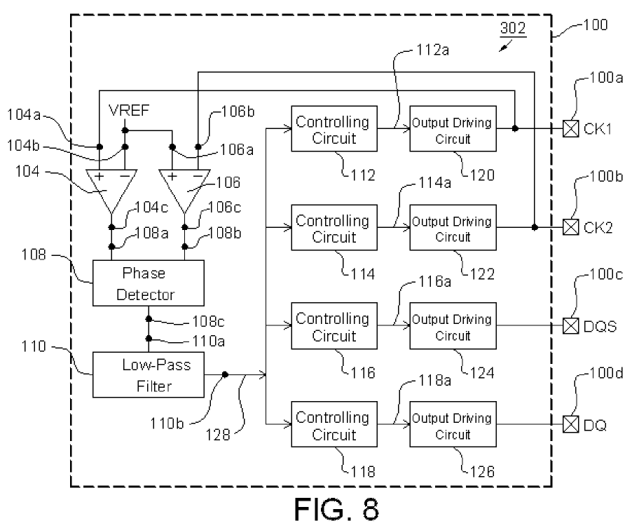

FIG. 8 shows a real-time calibrating circuit 302, which can achieve the object of calibrating the data strobe signal DQS and the data signal DQ by comparing the time sequence of the voltage cross point A and the voltage cross point E. The real-time calibrating circuit 302 shown in FIG. 8 is substantially identical to the real-time calibrating circuit 102 shown in FIG. 4, except that the second comparator 106 has its inputs 106a and 106b receive difference signals.

In the real-time calibrating circuit 302, the first comparator 104 receives the clock signal CK1 by its input 104a and receives the dc reference voltage VREF by its input 104b. In addition, the second comparator 106 receives the dc reference voltage VREF by its input 106a and receives the clock signal CK2 by its input 106b. Since the operation of the real-time calibrating circuit 302 is similar to the real-time calibrating circuit 102 shown in FIG. 4, it will not be illustrated herein in detail.

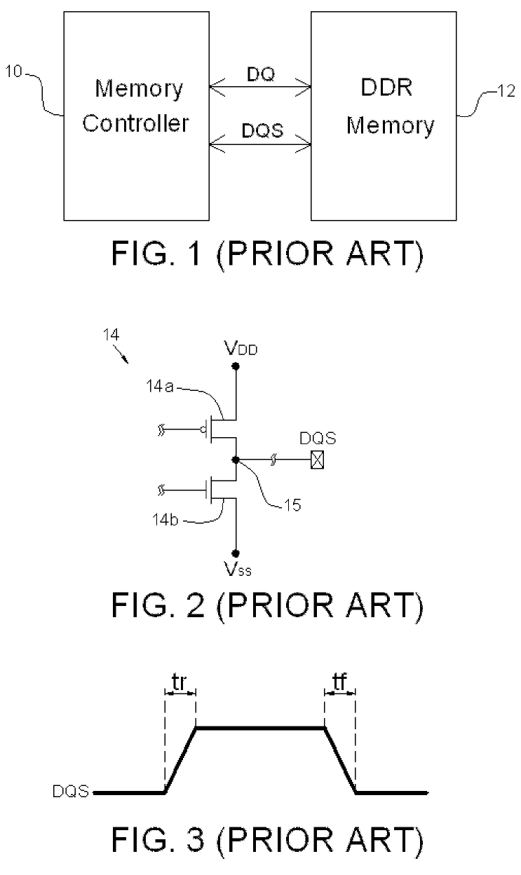

Please note that the real-time calibrating circuits 102, 202 and 203 according to the embodiments of the present invention instantaneously calibrate the data strobe signal DQS and the data signal DQ according to the driving performances of the clock signals CK1 and CK2. However, it should also be understood that any other two complementary signals can replace the clock signals CK1 and CK2 to achieve the object of the present invention. For example, in DDR II memory standard, two complementary data strobe signal are used and can replace the clock signals CK1 and CK2 to achieve the object of the present invention. In addition, it should be noted that the real-time calibrating circuits 102, 202 and 203 according to the embodiments of the present invention are not limited to be applied to a DDR memory controller. The real-time calibrating circuits 102, 202 and 203 can also be applied to any dynamic random access memory (DRAM), e.g. the DDR memory 12 as shown in FIG. 1. Furthermore, the data strobe signal DQS and the data signal DQ can be any data control signal and data signal utilized in other type of DRAM controller or DRAM memory, and are not limited to the data strobe signal DQS and the data signal DQ under the DDR memory standard.

Although the invention has been explained in relation to its preferred embodiment, it is not used to limit the invention. It is to be understood that many other possible modifications and variations can be made by those skilled in the art without departing from the spirit and scope of the invention as hereinafter claimed.

What is claimed is:

1. A real-time calibrating circuit for a data control signal and a data signal, comprising:
a first comparator for comparing a first signal and a second signal and outputting a first comparison signal;
a second comparator for comparing a third signal and a fourth signal and outputting a second comparison signal,
wherein two of the first signal, the second signal, the third signal and the fourth signal are complementary to each other, and both the two complementary signals have a high voltage level and a low voltage level;
a phase detector for receiving the first comparison signal and the second comparison signal and outputting a phase difference signal according to the phase difference between the first comparison signal and the second comparison signal;
two first output driving circuits for driving the two complementary signals respectively;
two first control circuits for adjusting the two first output driving circuits respectively according to the phase difference signal;
at least one second output driving circuit for driving at least one of the data control signal and the data signal; and
at least one second control circuit for adjusting the second output driving circuit according to the phase difference signal to calibrate at least one of the data control signal and the data signal.

2. The real-time calibrating circuit as claimed in claim 1, wherein the two first control circuits adjust driving abilities of the two first output driving circuits respectively according to the phase difference signal.

3. The real-time calibrating circuit as claimed in claim 1, wherein the second control circuit adjusts driving ability of the second output driving circuit according to the phase difference signal.

4. The real-time calibrating circuit as claimed in claim 1, wherein the first comparator outputs the first comparison signal according to a comparison result of the first signal and the second signal, wherein the comparison result corresponds to the voltage levels of the first and the second signals.

5. The real-time calibrating circuit as claimed in claim 1, wherein the second comparator outputs the second comparison signal according to a comparison result of the third signal and the fourth signal, wherein the comparison result corresponds to the voltage levels of the third and the fourth signals.

6. The real-time calibrating circuit as claimed in claim 1, wherein the two complementary signals are two complementary clock signals.

7. The real-time calibrating circuit as claimed in claim 1, wherein the first signal and the second signal are the two complementary signals.

8. The real-time calibrating circuit as claimed in claim 1, wherein the first signal and the third signal are the two complementary signals.

9. The real-time calibrating circuit as claimed in claim 1, wherein the two complementary signals are two complementary data control signals.

10. The real-time calibrating circuit as claimed in claim 1, wherein one of the first signal, the second signal, the third signal and the fourth signal is a direct-current voltage.

11. The real-time calibrating circuit as claimed in claim 10, wherein the direct-current voltage has a direct-current voltage level positioned at the middle of the high voltage level and the low voltage level of the two complementary signals.

12. The real-time calibrating circuit as claimed in claim 1, which is disposed in a dynamic random access memory (DRAM) controller.

13. The real-time calibrating circuit as claimed in claim 12, wherein the dynamic random access memory controller is a DDR memory controller.

14. The real-time calibrating circuit as claimed in claim 1, which is disposed in a dynamic random access memory (DRAM).

15. The real-time calibrating circuit as claimed in claim 14, wherein the dynamic random access memory is a DDR memory.

16. The real-time calibrating circuit as claimed in claim 1, further comprising a low-pass filter for filtering the phase difference signal and outputting a result signal.

17. The real-time calibrating circuit as claimed in claim 16, wherein the two first control circuits adjust the driving abilities of the two first output driving circuits respectively according to the result signal.

18. The real-time calibrating circuit as claimed in claim 16, wherein the second control circuit adjusts the driving ability of the second output driving circuit according to the result signal.

19. A real-time calibrating method for a data control signal and a data signal, comprising the following steps:
providing a first signal and a second signal being complementary to each other and both having a high voltage level and a low voltage level, wherein the first signal has a first cross point with the second signal at a first time;
providing a direct-current voltage having a direct-current voltage level positioned between the high voltage level and the low voltage level, wherein the direct-current voltage level has a second cross point with the first signal at a second time and a third cross point with the second signal at a third time; and
calibrating one of the data control signal and the data signal according to a time sequence of two of the first time, the second time and the third time.

20. The real-time calibrating method as claimed in claim 19, wherein the direct-current voltage level is positioned at the middle between the high voltage level and the low voltage level.

21. A real-time method for calibrating a data control signal and a data signal, comprising the following steps:
comparing a first signal and a second signal and outputting a first comparison signal;
comparing a third signal and a fourth signal and outputting a second comparison signal,
wherein two of the first signal, the second signal, the third signal and the fourth signal are complementary to each other, and both the two complementary signals have a high voltage level and a low voltage level;
receiving the first comparison signal and the second comparison signal and outputting a phase difference signal according to the phase difference between the first comparison signal and the second comparison signal;
driving the two complementary signals respectively;
adjusting two first output driving circuits respectively according to the phase difference signal;
driving at least one of the data control signal and the data signal; and
adjusting a second output driving circuit according to the phase difference signal to calibrate at least one of the data control signal and the data signal.

22. The method as claimed in claim 21, comprising:
adjusting driving abilities of the two first output driving circuits respectively according to the phase difference signal.

23. The method as claimed in claim 21, comprising:
adjusting the driving ability of the second output driving circuit according to the phase difference signal.

24. The method as claimed in claim 21, comprising:
outputting the first comparison signal according to a comparison result of the first signal and the second signal, wherein the comparison result corresponds to the voltage levels of the first and the second signals.

25. The method as claimed in claim 21, comprising:
outputting the second comparison signal according to a comparison result of the third signal and the fourth signal, wherein the comparison result corresponds to the voltage levels of the third and the fourth signals.

26. The method as claimed in claim 21, wherein one of the first signal, the second signal, the third signal and the fourth signal is a direct-current voltage.

27. The method as claimed in claim 26, wherein the direct-current voltage has a direct-current voltage level positioned at the middle of the high voltage level and the low voltage level of the two complementary signals.
